(19) United States
(12) Patent Application Publication
(10) Pub. No.: US 2016/0079059 A1
(43) Pub. Date: Mar. 17, 2016

(54) ELLIPTICAL WAFER MANUFACTURE

(71) Applicant: International Business Machines Corporation, Armonk, NY (US)

(72) Inventors: Stephen P. Ayotte, Bristol, VT (US); Dylan J. Fath, Winooski, VT (US); Michael C. Johnson, Burlington, VT (US); Travis S. Longenbach, South Burlington, VT (US); Nicolas E. Pizzuti, South Burlington, VT (US)

(21) Appl. No.: 14/488,617

(22) Filed: Sep. 17, 2014

(51) Int. Cl. H01L 21/02; H01L 31/0352; H01L 29/06; H01L 31/18; H01L 21/78; H01L 29/04

(52) U.S. Cl. CPC H01L 21/02433; H01L 21/78; H01L 21/02645; H01L 29/045; H01L 29/0657; H01L 31/18; H01L 31/035281

(57) ABSTRACT

An approach to manufacturing an elliptical semiconductor wafer includes a structure for an elliptical semiconductor wafer with a crystal direction, wherein the crystal direction is provided by a seed crystal orientation. The structure of the elliptical semiconductor wafer has a minor radius for the elliptical semiconductor wafer and a major radius for the elliptical semiconductor wafer wherein the major radius is greater than the minor radius.

### BACKGROUND OF THE INVENTION

The present invention relates generally to the field of semiconductor manufacture, and more particularly to semiconductor wafer manufacture.

In semiconductor manufacture, standard semiconductor wafer size increases from a 25.4 mm diameter to diameters of 200 mm and 300 mm. The increase in diameter size is driven by improvements in technology which have resulted in manufacturing efficiencies. These manufacturing efficiencies are possible, in part, as a result of the increased number of semiconductor chips in a single wafer. Prototypes of even larger semiconductor wafer sizes such as a 450 mm diameter are under development.

A semiconductor wafer is produced from a boule, which is a single crystal ingot composed of synthetically grown semiconductor material. A boule is commonly used for the creation of most semiconductor devices used in semiconductor chips. The boule is sliced to form the semiconductor wafers (e.g. thin slices of single crystal silicon). The semiconductor chips are then manufactured from the semiconductor wafer, commonly a silicon wafer. However, boules created from other semiconductor materials such as sapphire, gallium or compounds such as gallium arsenide may be used in semiconductor wafer manufacture for the production of semiconductor devices.

The single crystal of silicon making up the boule may have a specific crystal orientation or specific crystal direction that is used in determining a number of mechanical and electrical properties of the finished semiconductor wafer or semiconductor chips created from the semiconductor wafer. Semiconductor wafer properties effected by crystal orientation include mechanical strength, electrical properties such as carrier mobility, and slip plane orientation determining the intrinsic crystal fracture direction and shape (rectangular shape/orthogonal breaks or trapezoidal shape/angled breaks) for ease of wafer dicing. Crystal growth direction denoted by Miller direction indices such as <100> indicate the crystal direction and crystal orientation. Miller indices determine a family of lattice planes orthogonal to a direction denoted by three integers, h, k, and 1 related to the X, Y and Z directions in a crystal lattice. Traditionally, silicon semiconductor chips may be manufactured with a <100> or a <111> growth direction which correspond to the (100) planes and (111) planes respectively in a cubic crystal structure, although work has also been done on semiconductor wafers with a <110> crystal growth direction. The <110> crystal growth direction may provide better carrier mobility for increased switching rates in silicon semiconductor devices.

The boule used to produce semiconductor wafers is sometimes called an ingot, and may be produced by one or more commonly used methods. The methods used for growing single crystal boules include the Czochralski method, the Bridgeman-Stockbarger method, the floating zone method, and the Dash Necking method, which can produce a high purity single crystal. In most of these methods, processes have been developed using a precisely placed seed crystal. The seed crystal may be set in a specific orientation. The orientation of the seed crystal determines the orientation and resulting properties of the single crystal boule. A single crystal such as a silicon crystal grown from a seed crystal will grow with the same crystal orientation as the seed crystal thus, providing a boule with a specific crystal orientation.

Conventionally, the boule which may be a silicon crystal is sliced in the direction approximately perpendicular to the length of the boule (e.g. boule axis) which results in a nearly circular wafer. The boule is typically, a cylinder or nearly a cylinder in finished shape. The boule is cut using a wafer saw such as a wire saw or inner diameter wafer saw. In processes where the wafer is non-circular, a wafer grind is performed to create a circular wafer. The sliced circular semiconductor wafers may be finished with a chamfering or a notch process, edge grinding, a lapping process, an etching process and a polishing process.

### SUMMARY

Embodiments of the present invention provide elliptical semiconductor wafers and a method of manufacture of elliptical semiconductor wafers. A structure for an elliptical semiconductor wafer includes a crystal direction, wherein the crystal direction is provided by a seed crystal orientation, a minor radius for the elliptical semiconductor wafer and a major radius for the elliptical semiconductor wafer, wherein the major radius is greater than the minor radius.

Another structure for an elliptical semiconductor wafer includes an elliptical silicon on insulator semiconductor wafer including one or more elliptical semiconductor wafers with a crystal direction, wherein the crystal direction is provided by a seed crystal orientation. Additionally, the one or more elliptical semiconductor wafers have a minor radius for the elliptical semiconductor wafer and a major radius for the elliptical semiconductor wafer, wherein the major radius is greater than the minor radius. Furthermore, the elliptical silicon on insulator semiconductor has an insulating layer in one of the one or more elliptical semiconductor wafers.

A method of manufacture of an elliptical semiconductor wafer includes orienting a seed crystal and growing a boule from the seed crystal. The method further includes determining a wafer saw angle less than ninety degrees to a longitudinal axis of the boule and slicing the boule at the determined wafer saw angle to create an elliptical semiconductor wafer. Finally, the method includes performing elliptical wafer finishing operations on the elliptical semiconductor wafer.

### BRIEF DESCRIPTION OF THE DRAWINGS

FIG. 1 is an illustration of a wafer saw angle for a boule, in accordance with an embodiment of the present invention.

FIG. 2 depicts a top view of an elliptical semiconductor wafer used in semiconductor device manufacture in accordance with an embodiment of the present invention.

FIG. 3 is an exemplary process flow chart for elliptical semiconductor wafer manufacture according to an embodiment of the present invention.

### DETAILED DESCRIPTION

Economies of scale and technological improvements have driven changes to the size of a semiconductor wafer used in the manufacture of semiconductor chips. The semiconductor wafers used in the manufacture of a semiconductor chip continue to increase in size, driven mainly by an increase in the number of semiconductor chips produced on a larger semiconductor wafer. As the semiconductor wafer size increases from a 150 mm to a 300 mm wafer size, the number of 0.8 mm semiconductor chips per wafer increases by approximately seven times (about 130 chips/wafer to about 900 chips/wafer). Semiconductor wafer process steps for the fabrication of semiconductor devices such as field effect transistors (FET), capacitors and other similar devices include photolithography (resist apply, resist bake, etch, resist strip), metal deposit, oxide deposit, polysilicon apply, dielectric apply, for example, that can be performed at once on all semiconductor devices on a wafer. The wafer level process steps can result in a lower manufacturing cost per semiconductor chip when more semiconductor chips exist on a wafer. Complex semiconductor wafers may have multiple steps providing a fabrication cost advantage per semiconductor chip as the number semiconductor chips per wafer increase.

While providing economies of scale, the movement to larger than typical wafer sizes has not been without significant technical challenge. The technical challenges associated with handling and processing larger wafer sizes for increasingly complex semiconductor devices with shrinking feature sizes has proven to drive extremely large processing and processing equipment development. Included among the significant technical challenges associated with larger semiconductor wafer sizes are gravitational bending (wafer sag), flatness, even coating across larger areas, and vibrational effects. For example, as the migration to larger wafer sizes approaches 450 mm, the handling of 450 mm wafers requires the ability to handle silicon boules or ingots weighing approximately a metric ton. The technical challenges drive additional process development, tooling, engineering development and wafer process yield reductions that, along with the significant capital investment involved slow the move to larger semiconductor wafer size.

Embodiments of the present invention recognize the technical challenges associated with a migration to semiconductor wafer sizes of 450 mm and larger, provide an alternative approach to achieving a larger wafer size with increased wafer surface area for currently developed boule sizes and currently used single crystal growth processes by creating and utilizing elliptical wafers. Embodiments of the present invention provide a structure and a method of creating an elliptical semiconductor wafer that provides more surface area per wafer for a given boule diameter than a circular wafer created with existing processes from the same boule. The elliptical semiconductor wafers may also be produced with larger boule sizes under development. The larger elliptical semiconductor wafer with a larger wafer surface area provides the opportunity for more semiconductor chips per elliptical semiconductor wafer than a circular semiconductor wafer cut from the same boule. Embodiments of the present invention provide an opportunity for a larger semiconductor wafer sliced from a boule by using elliptical semiconductor wafers for applications such as silicon on insulator wafers (SOI) or photovoltaic cells (solar cells) compared to a circular wafer cut from the same boule. For example, an elliptical semiconductor wafer cut from a 150 mm boule with a minor radius of 75 mm and a major radius of 150 mm would provide approximately twice the wafer surface area of a circular 150 mm wafer with a 75 mm radius.

In an exemplary embodiment, an elliptical semiconductor wafer may be produced from a boule grown from a seed crystal oriented in the appropriate crystallographic direction to produce a desired crystal orientation when the boule is sliced at an oblique angle to the boule axis. The angle of the wafer saw to the boule axis is determined by the crystal orientation and the size of the elliptical semiconductor wafer desired. For example, a desired crystal orientation in silicon semiconductor wafers could be the <100> crystal direction, which corresponds to the (100) crystal plane in a cubic crystal structure, and since crystals oriented in this manner in a wafer may have a natural tendency (i.e. slip planes) to break or can be easily cut in rectangular or square shape. An elliptical wafer cut at a thirty degree angle to the boule axis would approximately double the available elliptical wafer surface area as compared to a circular wafer cut from the same boule.

A larger wafer surface area may be utilized in several ways for semiconductor manufacture. For example, a larger wafer surface area allows for an increase in the number of equivalently sized semiconductor chips per wafer. In an embodiment of the present invention, an elliptical semiconductor wafer processed through a semiconductor manufacturing process line appropriately tooled for an elliptical wafer may be processed to form semiconductor devices on the wafer and diced to create semiconductor chips. An elliptical wafer can create more semiconductor chips per wafer than a circular wafer produced from the same boule due to the larger elliptical wafer surface area. In another embodiment, an elliptical wafer may be used for SOI wafer or substrate thus creating a larger SOI wafer than a circular SOI wafer produced from the same size boule. In one embodiment, an elliptical wafer may be used to create larger photovoltaic cells (solar cells) after trimming to a rectangular shape than a square photovoltaic cell trimmed from a circular wafer from the same size boule.

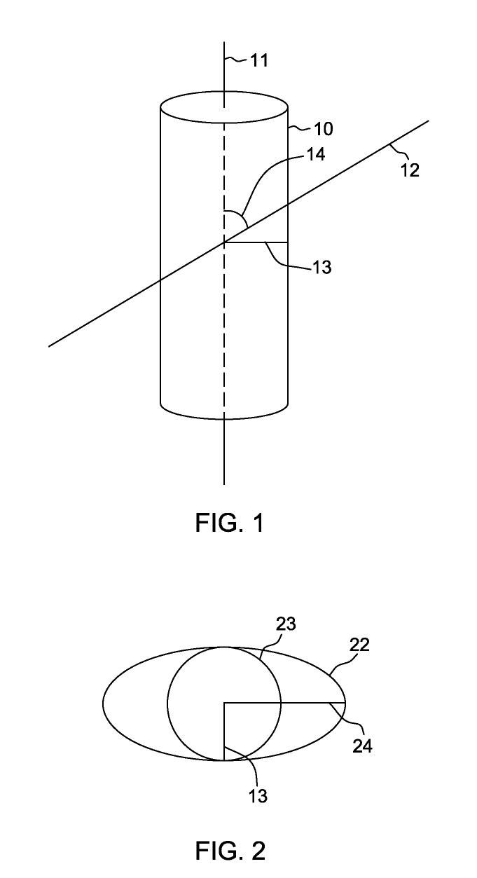

FIG. 1 is an illustration of a wafer slicing angle for a semiconductor boule, in accordance with an embodiment of the present invention. FIG. 1 is an illustration of semiconductor boule 10 with the ends (tail and neck area) of the boule removed creating a cylinder. The radius of boule 10 is depicted as radius 13. Boule axis 11 of boule 10, which is parallel to the length of the boule, is cut by a wafer saw. The wafer saw cut or wafer cut 12 is depicted at angle 14 to boule axis 11. Angle 14 may be determined by the desired crystal orientation as specified by the semiconductor device designer and the desired wafer surface for the elliptical wafer. In some embodiments, angle 14 may be determined using a desired elliptical wafer size or a desired crystal orientation.

FIG. 2 depicts a top view of an elliptical semiconductor wafer used in semiconductor device manufacture in accordance with an embodiment of the present invention. FIG. 2 depicts elliptical semiconductor wafer 22 which has a wafer surface created by the wafer cut 12 at angle 14 in boule 10 (FIG. 1). FIG. 2 provides an illustration of elliptical semiconductor wafer 22 cut at angle 14 as compared to a circular wafer 23 cut perpendicular to boule axis 11 through radius 13 in boule 10 (FIG. 1). Radius 13 is the minor radius of elliptical semiconductor wafer 22 and radius 24 is the major radius of elliptical semiconductor wafer 22, the major radius is greater than the minor radius.

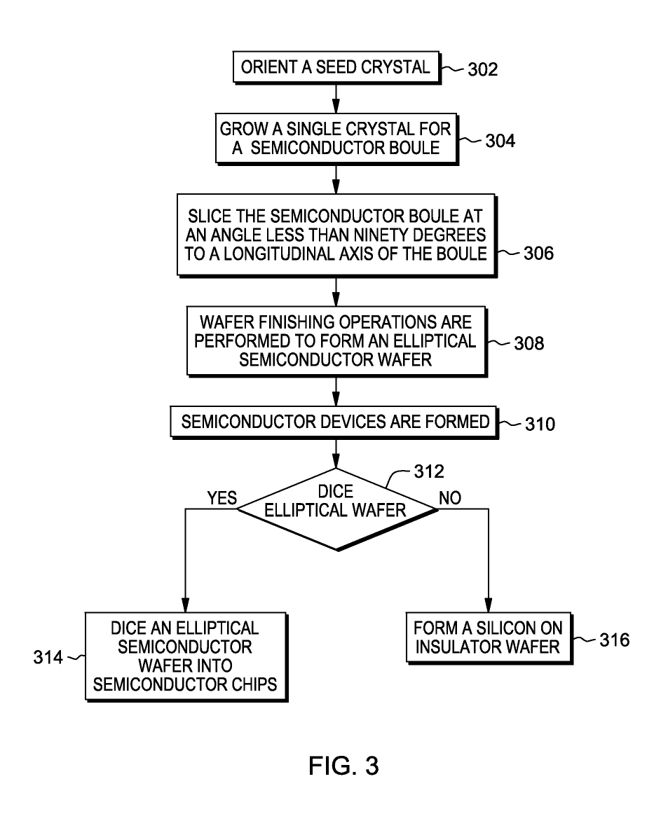

FIG. 3 is an exemplary process flow chart for elliptical semiconductor wafer manufacture, according to one embodiment of the present invention. FIG. 3 depicts the steps used in manufacture of an elliptical semiconductor wafer (steps 302 through 308) and the steps for manufacture of semiconductor devices on an elliptical semiconductor wafer (steps 310 through 316). The elliptical semiconductor wafer may be formed from a semiconductor boule. Semiconductor devices may be fabricated in the elliptical semiconductor wafer to create semiconductor chips or an elliptical SOI wafer. The order of the steps depicted in FIG. 3 and the number of steps depicted may be changed according to semiconductor manufacturing process line requirements and the semiconductor application design requirements.

In step 302, the elliptical semiconductor wafer process depicted for elliptical semiconductor manufacture orients a seed crystal. The seed crystal orientation may be accomplished using conventional seed crystal orientation techniques. A crystal direction provided by a seed crystal orientation of the seed crystal provides a desired or known crystal direction for a crystal orientation in the finished semiconductor boule. For example, a desired crystal direction may be a <100> crystal direction for a (100) crystal plane orientation in a silicon wafer. The desired or known crystal direction may be determined by a semiconductor circuit designer based on one or more of the following: the semiconductor material used, the electrical and mechanical properties required for the manufacture, the number of semiconductor chips desired per wafer, the wafer size, and the application for the finished semiconductor chip or elliptical wafer. For example, a desired seed crystal direction may be a <100> crystal direction in a finished silicon elliptical wafer and a large wafer surface area is desired. With these objectives, a designer may request a seed crystal orientation producing a silicon crystal with a <100> crystal direction in an elliptical silicon wafer cut at a thirty degree angle to the boule axis.

In step 304, the elliptical semiconductor wafer process depicted for elliptical semiconductor wafer manufacture grows a single crystal for a semiconductor boule. Using one or more of single crystal growth processes, for example, a Czochralski method, a floating zone method, a Dash Necking method, a Bridgeman-Stockbarger method, or another single crystal growth method, a single semiconductor crystal may be grown into a semiconductor boule. The crystal orientation of the boule matches the crystal orientation of the seed crystal. The diameter, crystal purity, and crystal defect of the boule may be determined by single crystal growth processes and parameters used in semiconductor boule formation, for example, a pull rate or spin.

In step 306, the elliptical semiconductor wafer process depicted for elliptical semiconductor manufacture slices the semiconductor boule at an angle less than ninety degrees to a longitudinal axis of the boule. In the exemplary embodiment, the wafer saw slices a boule at an angle less than ninety degrees to the boule axis. A wafer saw angle less than seventy five degrees may be used to produce an elliptical wafer in one embodiment. The wafer saw angle for slicing a boule to form an elliptical wafer is determined by the semiconductor designer, based in part, on the desired crystal orientation of the semiconductor single crystal (i.e. semiconductor application, manufacturing and wafer size desired). For example, a wafer saw angle less than thirty degrees to the boule axis may be used to create an elliptical semiconductor wafer. In another example, a wafer saw angle of thirty degrees creates an elliptical wafer with a major axis twice as long as the minor axis which is also the boule radius. The smaller the wafer saw angle to the boule axis, the larger the resulting elliptical wafer surface area. A smaller wafer saw angle to the boule axis, for example, a forty degree angle to the boule compared to a seventy degree wafer saw angle to the boule axis, the longer the major axis of the elliptical wafer and the larger the resulting semiconductor wafer surface area.

The wafer saw angle determines the major radius of the elliptical semiconductor wafer using a sine of the wafer saw angle. For example, the sine of the wafer saw angle is equal to the radius of the boule (i.e. the minor radius of the elliptical wafer) divided by the major radius of the elliptical wafer.

The wafer saw used to slice the boule may be an inside diameter wafer saw, a wire wafer saw, a multi-wire wafer saw, or other wafer saw used in the manufacture of semiconductor wafers to slice or cut a single crystal such as a silicon boule or other semiconductor boule to form a semiconductor wafer. A notch, flat cut or other crystal orientation or similar identification of the boule may be made after the wafer is sliced. A wafer mark or wafer identification such as laser dot coding may be applied to the sliced elliptical semiconductor wafer. Once the wafer is sliced orthogonally to the boule axis creating an elliptical wafer, conventional wafer handling equipment is modified to accommodate an elliptical wafer form factor.

In the exemplary embodiment, the ends of the semiconductor boule (i.e. a tail and a neck of a grown crystal) may be cropped or sliced off the boule, prior to wafer slicing, creating a cylinder. In an embodiment, the semiconductor crystal orientation may be verified, crystal conductivity and resistivity may be measured prior to wafer slicing. In some embodiments, diameter grinding of the semiconductor boule or other boule process operations may be performed prior to step 306.

In step 308, wafer finishing operations are performed to form an elliptical semiconductor wafer. Semiconductor wafer finishing operations may include wafer lapping to improve wafer flatness and remove mechanical defects (e.g. wafer saw marks), wafer etching, wafer polishing (e.g. chemical mechanical polish (CMP)), wafer cleaning, wafer marking, for example. Semiconductor finishing operations for an elliptical semiconductor may include handling equipment and processes which have been modified to accommodate an elliptical wafer form factor rather than a circular wafer form factor. The exemplary elliptical semiconductor finishing operations include wafer lapping, CMP, wafer cleaning, and wafer marking. Upon completion of the wafer finishing operations, the elliptical semiconductor wafer is formed.

In step 310, semiconductor devices are formed. Semiconductor devices such as digital devices, field-effect transistors (FETs or finFETs), passive devices (e.g. capacitors), solar devices, mixed signal devices or other similar semiconductor devices used in electronic circuit manufacture may be created on an elliptical semiconductor wafer using standard wafer processing equipment and processes modified for an elliptical wafer form factor. For example, semiconductor device formation may include conventional processes such as reactive ion implant, damascene processes with photolithography, metal deposition, barrier layer deposition, oxide layer formation, polysilicon deposit and metallization, dielectric materials, through silicon vias and interconnect vias as created in the back end of the line (BEOL) semiconductor device fabrication may be modified as needed for use with elliptical wafer handling equipment. Semiconductor device processes may be modified for elliptical wafers. In one embodiment, photovoltaic cell (i.e. solar cell) processes for a circular silicon wafer may be modified for an elliptical wafer. Using elliptical wafer handling equipment, photovoltaic cells may be produced from photovoltaic processes modified as needed for an elliptical form factor. In an embodiment, an insulating layer such as a buried oxide layer may be formed on one or more elliptical semiconductor wafers in addition to forming semiconductor devices. One or more elliptical semiconductor wafers which may have an insulating layer may be bonded together to form an elliptical silicon on insulator wafer using standard wafer bonding techniques.

In decision block 312, it is determined whether to dice the elliptical wafer or not to dice the wafer. Depending on the wafer design for the semiconductor circuits determined by the wafer application and semiconductor designer, the elliptical wafer may be diced or may remain in elliptical wafer form (SOI).

In step 314, an elliptical semiconductor manufacture process dices an elliptical wafer into semiconductor chips (the “yes” branch of decision block 312). The elliptical semiconductor wafer with semiconductor devices formed and BEOL processes and interconnections completed may be diced into semiconductor chips. An elliptical semiconductor wafer diced into semiconductor chips may yield more chips per wafer than a circular wafer cut from the same boule depending on the semiconductor chip size and shape. In an embodiment, the semiconductor chip designer may optimize the size and shape of the elliptical wafer (i.e. the major axis and minor axis of the ellipse) to the size and shape of the semiconductor chip. In one embodiment, the elliptical semiconductor wafer may be trimmed to form a photovoltaic cell. The photovoltaic cell may be trimmed to form a rectangle, an octagon, a rectangle with notched corners or other trimmed shape for a photovoltaic cell. An elliptical semiconductor wafer may provide a larger photovoltaic cell than a circular wafer from the same boule and may not require as precise orientation of the seed crystal as some semiconductor devices.

In step 316, the elliptical semiconductor wafer forms a silicon on insulator (SOI) wafer (the “no” branch of decision block 312). One or more elliptical semiconductor wafers may be used in the creation of elliptical SOI wafers. A buried oxide layer (BOX) or other insulating layer may be formed in an elliptical semiconductor wafer using known processes such as Separation by Implantation of Oxygen (SIMOX) process. Alternatively, elliptical silicon on insulator wafers may be formed from two elliptical semiconductor wafers when one of the elliptical semiconductor wafers has been oxidized on the top surface forming a top surface insulating layer on one of the two elliptical semiconductor wafers. One of the two elliptical semiconductor wafers without an insulating layer may be bonded to the insulating layer on the top surface of the elliptical semiconductor wafer which may have been oxidized. The two elliptical semiconductor wafers may be bonded utilizing SOI wafer joining techniques for wafer bonding such as adhesives and diffusion bonding. In an embodiment, through silicon vias may be etched and formed in the elliptical silicon on insulator wafer. Semiconductor devices such as active, passive, optical, photovoltaic cells, or mixed signal devices may be formed in the elliptical silicon on insulator wafer. In another embodiment, the elliptical silicon on insulator wafer may be composed of another semiconductor material such as Ge, GaAS, InAs, another semiconductor material or compound semiconductor material instead of silicon or another insulator such as sapphire. The bonded elliptical semiconductor wafers can form a larger SOI wafer compared to a circular SOI wafer formed from the same boule and, thus may provide more function, that is, may provide more semiconductor circuits for the SOI wafer.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. Further, the figures are not necessarily to scale, and some features may be exaggerated to show details of particular components. Therefore, specific structural and functional details disclosed herein are not to be interpreted as limiting, but merely as a representative basis for teaching one skilled in the art to variously employ the methods and structures of the present disclosure.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In some embodiments, the elliptical wafers formed by the embodiments of the present invention may be diced in semiconductor chip form. The resulting semiconductor chips can be distributed by the fabricator in raw wafer form (that is, as a single wafer that has multiple unpackaged chips), as a bare die or in a packaged form. In the latter case, the chip is mounted in a single chip package (such as a plastic carrier, with lead that is affixed to a motherboard or other higher level carrier) or in a multichip package (such as a ceramic carrier that has either or both surface interconnections or buried interconnections). In any case the chip is then integrated with other chips, discreet circuit elements, motherboard, or end product. The end product can be any product that includes integrated circuit chips, ranging from toys and other low-end applications to advanced computer products having a display, a keyboard or other input device and a central processor.

What is claimed is:

1. An elliptical semiconductor wafer, comprising:
a crystal direction, wherein the crystal direction is provided by a seed crystal orientation; and
a minor radius for the elliptical semiconductor wafer and a major radius for the elliptical semiconductor wafer, wherein the major radius is greater than the minor radius.

2. The elliptical semiconductor wafer of claim 1, further comprises the major radius for the elliptical semiconductor wafer determined by a wafer saw angle measured to a longitudinal axis of a boule.

3. The elliptical semiconductor wafer of claim 1, wherein the crystal direction is determined based, at least in part, on at least one of: a semiconductor material used, a number of semiconductor chips per wafer, a wafer size, and an application for the elliptical semiconductor wafer.

4. The elliptical semiconductor wafer of claim 1, wherein the minor radius is a diameter of a boule used to form the elliptical semiconductor wafer.

5. The elliptical semiconductor wafer of claim 1, further comprises forming one or more semiconductor devices on the elliptical semiconductor wafer.

6. The elliptical semiconductor wafer of claim 5, wherein the one or more semiconductor devices are at least one of: an active device, a passive device, a photovoltaic cell, or a mixed signal device.

7. The elliptical semiconductor wafer of claim 6, further comprises a rectangular photovoltaic cell.

8. An elliptical silicon on insulator semiconductor wafer, comprising:
one or more elliptical semiconductor wafers;
a crystal direction, wherein the crystal direction is provided by a seed crystal orientation;
a minor radius for each of the one or more elliptical semiconductor wafers and a major radius for each of the one or more elliptical semiconductor wafers, wherein the major radius is greater than the minor radius; and
an insulating layer in one of the one or more elliptical semiconductor wafers.

9. The elliptical silicon on insulator wafer of claim 8, wherein the elliptical silicon on insulator semiconductor wafer further comprises:
a first elliptical semiconductor wafer, wherein the first elliptical semiconductor wafer includes an insulating layer on a top surface of the first elliptical semiconductor wafer;
a second elliptical semiconductor wafer, wherein the second elliptical semiconductor wafer is bonded to the top surface of the first elliptical semiconductor wafer; and
one or more semiconductor devices on at least one of the one or more elliptical semiconductor wafers.

10. The elliptical silicon on insulator semiconductor wafer of claim 8, wherein the one or more semiconductor devices are at least one of: an active device, a passive device, a photovoltaic cell, or a mixed signal device.

11. The elliptical silicon on insulator semiconductor wafer of claim 8, wherein the two or more elliptical semiconductor wafers have a minor radius for the elliptical silicon on insulator semiconductor wafer and a major radius for the elliptical silicon on insulator semiconductor wafer, wherein the major radius is greater than the minor radius.

12. A method of manufacture of an elliptical semiconductor wafer, the method comprising:
orienting a seed crystal;
growing a boule from the seed crystal;
determining a wafer saw angle less than ninety degrees to a longitudinal axis of the boule;
slicing the boule at the determined wafer saw angle to create an elliptical semiconductor wafer; and
performing elliptical wafer finishing operations on the elliptical semiconductor wafer.

13. The method of claim 12, further comprises:
forming one or more semiconductor devices on the elliptical semiconductor wafer; and
dicing the elliptical semiconductor wafer into semiconductor chips.

14. The method of claim 12, further comprises:
slicing the boule at the determined wafer saw angle to create one or more elliptical semiconductor wafers;
forming an insulating layer on the one or more elliptical semiconductor wafer;
forming semiconductor devices on the one or more elliptical semiconductor wafer; and
bonding the one or more elliptical semiconductor wafers together to form an elliptical silicon on insulator semiconductor wafer.

15. The method of claim 12, wherein orienting a seed crystal further comprises determining a seed crystal direction that provides a crystal direction in the elliptical semiconductor wafer.

16. The method of claim 15, further comprises determining the crystal seed direction based, at least in part, on one or more of the following: a desired crystal direction, one or more mechanical properties, one or more electrical properties, a wafer size, a number of chips per wafer, a semiconductor material, and a semiconductor device application.

17. The method of claim 12, wherein determining a wafer saw angle less than ninety degrees to the longitudinal axis of the boule further comprises at least one of the following: determining a desired major radius for the elliptical semiconductor wafer, determining a wafer saw angle according to a crystal direction, and determining the wafer saw angle for a number of semiconductor chips per elliptical wafer.

18. The method of claim 12, wherein determining the wafer saw angle further comprises determining an elliptical semiconductor wafer size based, at least in part, on the semiconductor chip size and shape.

19. The method of claim 13, wherein the one or more semiconductor devices on the elliptical semiconductor wafer are at least one of: an active device, a passive device, a photovoltaic cell, or a mixed signal device.

20. The method of claim 12, further comprises forming one or more photovoltaic cells on the elliptical semiconductor wafer and trimming the elliptical semiconductor wafer to a rectangular shape.
